(19) United States
(12) Patent Application Publication
(10) Pub. No.: US 2015/0070037 A1
(43) Pub. Date: Mar. 12, 2015

(54) TEST FIXTURE FOR PROBE APPLICATION

(71) Applicant: Apple Inc., Cupertino, CA (US)

(72) Inventors: Anuranjini Pragada, Cupertino, CA (US); Terrence L. Van Ausdall, Cupertino, CA (US); Steven P. Hotelling, Cupertino, CA (US)

(21) Appl. No.: 14/450,714

(22) Filed: Aug. 4, 2014

Related U.S. Application Data
(60) Provisional application No. 61/875,380, filed on Sep. 9, 2013.

(51) Int. Cl. G01R 1/067; G01R 27/26; G01R 1/04

(52) U.S. Cl. CPC G01R 1/06705; G01R 1/0408; G01R 27/2605
USPC 324/754.03; 324/755.01; 324/756.01

(57) ABSTRACT

Systems and methods to fixture and utilizing a probe which tests a capacitive array are described herein. A support bracket with freedom about a plurality of axes may aid in locating a probe and allowing the probe to contact multiple surfaces consistently. By utilizing the support bracket, the angle between a test probe and a contact surface may be minimized such that the surface of the test probe and the contact surface may rest flat against one another. The system may also limit the force translated through support bracket. This system and method may allow for a high degree of accuracy and a high degree of precision during contact of the test probe and the test surface.

### CROSS-REFERENCE TO RELATED APPLICATION

This application is a nonprovisional patent application of and claims the benefit to U.S. Provisional Patent Application No. 61/875,380, filed Sep. 9, 2013 and titled “Test Fixture for Probe Application,” the disclosure of which is hereby incorporated by reference herein in its entirety.

### TECHNICAL FIELD

This application generally relates to the use of a probe for testing a capacitive array, and more particularly to the device that aids the probe in making consistent tests between test subjects.

### BACKGROUND

A fingerprint sensor system can include a fingerprint sensor to which the user can apply their finger, or a portion thereof. The fingerprint sensor may image one or more features of the finger, such as ridges and valley of a fingerprint. A “fingerprint image” or “captured fingerprint image” may be represented by, or be analogous to, a data set abstracted from such an image, one example of which is a ridgeflow map. The fingerprint sensor system can be coupled to a processing unit (as described herein, below), which can maintain a fingerprint information database, and which can attempt to match the captured image against information about known fingerprints from known users.

For example, when the processing unit or other element matches the captured fingerprint image against a known fingerprint from an authorized user, the processing unit can take one or more actions in response thereto. For example, the processing unit can authorize usage of a device for an individual procedure, for a sequence of procedures, for a selected time duration, until a trigger indicating that the user is no longer authorized, or until the user de-authorizes the device. For example, the user can de-authorize the device by turning the device off, or by handing the device to another user. For example, the device can be a smart phone, tablet computing device, portable computer, touch screen on an appliance or automobile or similar device, or any other device having touch device capability

While the use of fingerprint readers are becoming more prolific, there is an absence of testing and calibration processes and devices to ensure the accuracy and precision of fingerprint reader to fingerprint reader. Because fingerprint readers rely on the accuracy of recording an image and comparing that image to a prerecorded image, any change in condition may create insurmountable obstacles to the consistent functionality of the fingerprint reader. As such, even similar fingerprint readers may not recognize all fingerprints with the same level of accuracy due to variability of types of fingers, types of fingerprints, changes in user behavior day to day and electronic noise inherent in the devices. A lack of capable testing or calibration systems in the industry may be driving up costs and producing inferior fingerprint readers.

### SUMMARY

Generally, the consistency of a fingerprint reader between test subjects may be improved by utilizing a system to test and calibrate the fingerprint reader. A probe which mimics a figure or the electrical characteristics of a finger, but with known values via the probe's manufacture, may be utilized to test or calibrate a fingerprint sensor.

Improving consistent contact between a probe and the test surface may improve testing conditions. As such, in accordance with various embodiments, a probe apparatus may comprise a housing and a probe having a contact surface that extends below the bottom surface of the housing. The probe apparatus may also comprise a support bracket having freedom about at least two axes and connected to the probe; wherein the probe is operable to move freely about at the least two axes to adapt to a misalignment of the contact surface with another surface.

In accordance with other embodiments, a test fixture may comprise a base, an intermediate base, an arm and a probe housing. The arm may include an upper spring plate and a lower spring plate operable to maintain an un-fixed end of the arm substantially vertical. The probe housing may be attached to the bottom surface of the arm and have a contact surface that extends from the housing and is operable to contact a flat surface. The support bracket may have freedom about at least two axes and connecting the probe to the housing. Further, the probe may be operable to move freely about the at least two axes.

Another embodiment may take the form of a method for testing a capacitive array, including the operations of: lowering a first probe toward a test platform; contacting the test platform with a contact surface of the first probe; determining if the first probe is in angular alignment with the test platform; if not, repositioning the contact surface of the first probe relative to a surface of test platform; and taking a first measurement from the probe based on the first probe's capacitive profile.

It is to be understood that both the foregoing general description and the following detailed description are for purposes of example and explanation and do not necessarily limit the present disclosure. The accompanying drawings, which are incorporated in and constitute a part of the specification, illustrate subject matter of the disclosure. Together, the descriptions and the drawings serve to explain the principles of the disclosure.

### BRIEF DESCRIPTION OF THE DRAWINGS

FIG. 1 shows a conceptual drawing of a probe applied to a sensor.

FIG. 2A shows a first conceptual drawing of a probe coming into contact with a biometric module test platform.

FIG. 2B shows a second conceptual drawing of a probe coming into contact with a biometric module test platform.

FIG. 2C shows a third conceptual drawing of a probe coming into contact with a biometric module test platform.

FIG. 2D shows a sample structure utilized to limit or prevent a probe support bracket from absorbing excessive force.

FIG. 3A shows a first example device that supports a probe and allows probe rotation about at least two axes.

FIG. 3B shows a second example device that supports a probe and allows probe rotation about at least two axes.

FIG. 3C shows a third example device that supports a probe and allows probe rotation about at least two axes.

FIG. 3D shows a fourth example device that supports a probe and allows probe rotation about at least two axes.

FIG. 3E shows a fifth example device that supports a probe and allows probe rotation about at least two axes.

FIG. 4A shows a first view of an example apparatus for applying a probe to a fingerprint sensor.

FIG. 4B shows a second view of an example apparatus for applying a probe to a fingerprint sensor.

FIG. 4C shows a third view of an example apparatus for applying a probe to a fingerprint sensor.

FIG. 5 shows an example flow chart depicting the method of using a fingerprint sensor probe.

### DETAILED DESCRIPTION

Generally, embodiments disclosed herein may take the form of an apparatus or method for improving the consistency of a finger probe application to test subjects. Specifically, a probe which mimics a finger or the electrical characteristics of a finger, but with known values, is utilized to test or calibrate a fingerprint sensor. In order to accurately and precisely contact the probe flatly against the fingerprint sensor, a support bracket may be used to allow for either the fingerprint sensor or the probe to enjoy freedom of movement about a plurality of axes. This freedom may allow the probe or the fingerprint sensor test platform to adapt to the angle of the surface of the other.

Although specific embodiments are discussed with respect to a probe and apparatus for a fingerprint sensor test platform, it should be appreciated that embodiments may be used or incorporate a probe and/or test apparatus for any suitable biometric sensor. Accordingly, embodiments herein should be construed as encompassing probes and/or test structures for biometric sensors in general.

Additionally, as discussed herein, a system may be utilized to move the probe in the x, y, and z axes in order to properly align, target, and engage the probe against various fingerprint sensor test platforms. This system may also be able to absorb or control the force, in the z direction, of the probe against the fingerprint sensor test platform. By utilizing one or more of these device and processes, higher quality fingerprint sensors can be manufactured or calibrated.

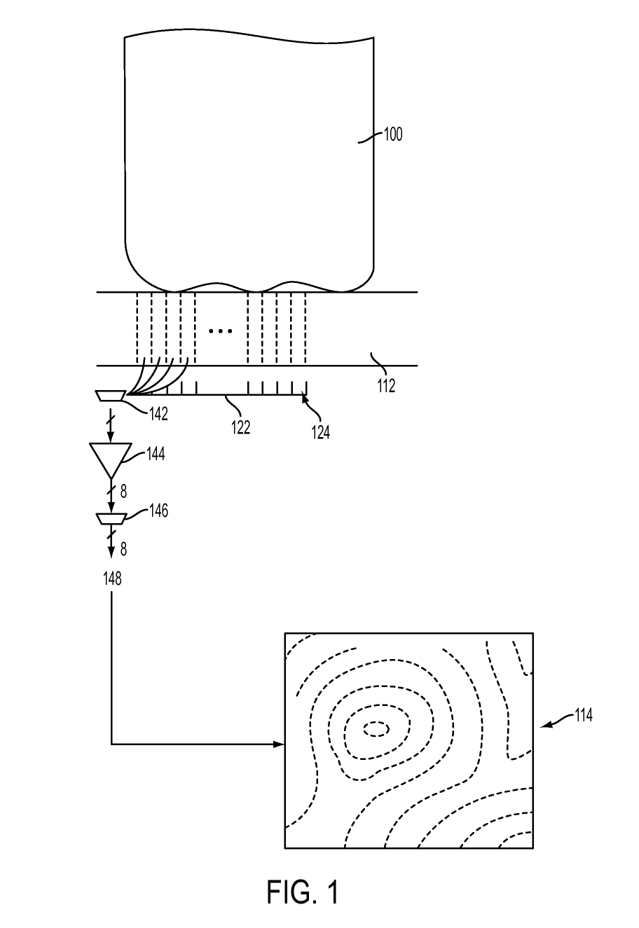

FIG. 1 shows a conceptual drawing of application of a probe to a fingerprint sensor. A fingerprint sensor system includes a dielectric element 112, to which, and under normal operation, a user applies a finger, or a portion thereof, so that an associated sensor 122 may generate a captured fingerprint image. For example, the dielectric element 112 can include or be part of a cover glass element of a device, such as the display image cover of a tablet computing device, a smart phone, or similar device. The cover glass element can be formed from a dielectric such as sapphire, glass, chemically treated glass, plastic, resin, or some other material suited to the purposes or functions described herein. In another embodiment, the dielectric element 112 may be part of a button or other input element. The input element may be formed from any of the materials previously discussed with respect to the cover glass. Any suitable fingerprint sensor may be used with embodiments and techniques disclosed herein. Suitable fingerprint sensors include capacitive sensors, ultrasonic sensors, optical sensors, pyro-electric sensors, and so on.

During normal field operation a user would place his finger in contact with the dielectric element 112. However, under a testing or calibration procedure, a probe 100 may be used instead of a finger. The probe may be a model of a finger, not a true finger, but it may be representative of a class of finger or generally similar to an average finger. To achieve this, the probe 100 may be a device operable to have a capacitive profile representative of a class of fingers. Generally, the probe may be formed of any of a variety of materials that are able to be detected by the fingerprint sensor in a fashion similar to a real finger. In one embodiment, the core of the probe may be a conductive material such as a metal. For example, steel, aluminum, or titanium may form a part or a majority of the probe 100. Alternatively, other non-metallic materials such as a conductive plastic may be used as well.

In accordance with various embodiments, the probe 100 may also include a coating to further mimic or match the surface of a finger. One aspect of a coating that may facilitate mimicking or matching certain characteristics of a finger, or more particularly skin, is the thickness of the coating. In some embodiments, the coating may be a thin layer of material deposited on the probe 100 sufficient to simulate the electrical characteristics of skin. The layer may be deposited in a variety of thicknesses or may have a uniform thickness. In one example, layer may be 10 microns thick. However, it may be noted that the coating may be more than 10 microns thick or less than 10 microns thick. However, the thickness of the coating between two like probes (i.e. probes representing similar classes of fingers) may be substantially the same thickness.

Where two like probes may have different thicknesses of coatings, such as plus or minus one or two microns, it should be noted that that is a relatively large variance. For example, a difference of a single micron in what is supposed to be a 10 micron thick coating is a 10% change. Such variances in what are supposed to be similar or identical probes may lead to poor quality and/or high variance measurements by the sensor during a test. Accordingly, the various physical dimensions of a probe, including the thickness of any given coating, may be carefully controlled.

In accordance with various embodiments, the coating may be any coating that simulates the electrical characteristics of skin. This applies to material as well as thickness. For example, the coating may be made from poly (p-xylylene) polymer (e.g. parylene). While parylene is commonly used as an environmental barrier for circuit boards and the like, it is durable and allows for deposition and formation of very thin layers. Parylene may also function as a moisture shield for the probe substrate. Parylene has electrical characteristics that are reasonably close to, or the same as, skin and is reasonably controllable when being deposited on the probe substrate. In another embodiment, the coating may be a titanium dioxide layer. In many aspects, titanium dioxide may also simulate certain characteristics of a finger, particularly the electrical characteristics of skin. Similarly, other materials that can be deposited in a thin coating on the probe substrate may be utilized.

Since industrial production of fingerprint readers is often done in large batches, there may be a correspondingly large number of probes utilized to test and calibrate each and every one. As such, controls to improve consistency between similar probes may improve the end fingerprint reader product. As such, in one embodiment, secondary processing may be utilized to control the thickness of the coating. For example, the coating may be machined or undergo a similar process to ensure consistent thickness between like probes. While all probes may not be alike since various probes may be configured to represent various classes of fingers, each probe in a class may none-the-less have a substantially similar representation of the same finger. As discussed in more detail below, multiple probes may be used representing multiple classes of fingers in a single test setup.

In accordance with various embodiments, the probe 100 may create a certain known signal to be imaged. By controlling the specifications and parameters of the application of probe 100, a measured signal and resulting image from the probe 100 can be compared to the known signal and resulting image. The compared signals may form a correlated noise picture of an image that may be used in a noise canceling algorithm which may compensate for noise, blurriness, or other image errors in images that are captured after calibration. The process allows for an indication of the sensor's image quality under normal operation. This may allow consistent qualification, calibration, and testing of multiple fingerprint reading platforms.

As shown in FIG. 1, a sensor 122 may include an array of sensor elements 124, each of which can provide an analog signal describing the probe 100 located above the sensor elements 124. While under normal operation, sensor elements 124 provide an analog signal describing a fingerprint of a user. The sensor provides a set of signals, each of which indicates information regarding the applied test subject, e.g., a finger or the probe 100. This information may be a measurement of capacitance between each of the sensor elements 124 and a portion of a user's finger. As one example, greater capacitance may indicate a ridge of a fingerprint overlies a sensor element 124, while a lower capacitance may indicate a valley of a fingerprint overlies a sensor element.

It may be appreciated that, under normal operations, the sensing of the fingerprint may be done in a variety of conditions. Further, numerous different fingerprints may be read and processed. In addition, numerous other processing steps (such as signal amplification) and various interferences (such as fixed pattern noise) may affect the final viability of information that the system can reasonably use. Some example processing steps are discussed herein.

Still with respect to FIG. 1, each of the set of signals corresponds to, or is generated by, an individual sensor element 124. The sensor elements 124 may be arranged in a grid or array, in a line, or in any other suitable pattern. Additionally, the sensor elements 124 may be used with swipe sensors, two-dimensional sensors, and the like.

In one embodiment, a multiplexer 142 collects the analog signals from the sensor elements 124 of the sensor 122, and multiplexes them together into sets of multiple image element signals. The image element signals are coupled to one or more amplifiers 144. The amplifiers 144 receive relatively weak signals, and amplify them to become relatively stronger signals. For example, the amplifiers 144 can increase the dynamic range of the fingerprint image element signals so they cover the scope of possible relative strength.

Further, a set of outputs from the amplifiers 144 are coupled to inputs of a corresponding set of analog to digital (“A/D”) converters 146. The A/D converters 146 receive analog input signals and generate digital output signals representing the same relative strength. This can have the effect of providing a set of digital signals 148. For example, the digital signals 148 may each describe an eight-bit representation of a fingerprint image element.

The digital signals 148 collectively may be processed to provide an image 114 which may represent a fingerprint under normal operation or a probe during calibration and testing. The image is shown in the figure as having a set of ridges or ridge-lines. It might occur that the fingerprint sensor system can successfully determine whether the image 114 definitively matches or definitively does not match any known information. This comparison may be used for calibrating the system. Because the profile of the probe 100 is known, the measured image and the known image may be compared and utilized to adjust the system to cancel out unwanted noise.

Under normal operation the fingerprint measured by the image may be compared to known images and the fingerprint sensor system can inform the processing unit to authorize usage of the device (or refuse to authorize usage of the device) in response to a suitable match. This comparison may be improved by the initial calibration or testing performed with the probe 100, thus potentially allowing for less manipulation of the fingerprint image 114 during normal operation in order to accurately compare a measured image with a stored image.

Because the probe 100 may be used in various embodiments to calibrate the system, it may desirable to create an accurate and precise measurement of the probe during the test procedure in order to compare the measured image to the known image of the probe. In order to obtain an accurate and precise measurement of the probe, certain characteristics of the test procedure may be controlled. For example, the location of the probe relative to the sensor can be controlled. By reading different locations of the probe with different sensor elements, it is more difficult to compare a known image the recorded image. As such, by keeping the location of the probe relative to the sensor consistent when testing moves from sensor to sensor, the comparison of the known image of the probe to the recorded image of the probe is may likewise be kept relatively consistent. Therefore, the comparison of the known image of the probe to the recorded image of the probe may highlight only the noise produced by the system. As such, the comparison may aid in removing this noise from the system.

In another example, the force with which the probe contacts the cover glass can be controlled. Similarly to controlling the location of the probe, controlling the force of the probe on the cover glass may improve the final results. Changes in the force between the probe and the cover glass may results in differences in the measured signals. By ensuring the consistency between tests relative to the contact force of the probe 100, the comparison between the known and measured signals from the probe may be improved.

In another example, position (e.g., angle) of the contact surface of the probe relative to the surface of the cover glass can be controlled. The flatter the probe contact surface is relative to the surface of the cover glass, the more accurate and precise the measurements of the probe may be. For example, if the probe 100 doesn't lay flat on the cover glass, the measured signal from the probe 100 can be significantly different than the known signal. By improving the system's ability to lower the probe 100 onto a cover glass and improving the ability of the system to land the probe's contact surface on the cover glass flat or substantially flat, the measured signal from the probe 100 is improved.

In accordance with various embodiments, the system may be tested in two ways. In one embodiment, the system may be tested by communicating directly with a sensor module (which may already be placed beneath a dielectric, such as a cover glass or input element) through a test connection linked to the sensor. In another embodiment, the system may be tested by communicating through native software. Either way, the probe assemblies may be the same or similar. It may also be noted that the fingerprint sensor system may be calibrated or tested at any point during the manufacturing process. In one example, the probe may be applied very early in the manufacturing process by applying it directly to a fingerprint sensor. Early application to the fingerprint sensor hardware may allow for greater consistency by simplifying the testing implementation.

In another example, the probe may be applied during the assembly process of the electronic device incorporating the fingerprint sensor. In this example, while the device may not be entirely assembled, the fingerprint sensor may be operated by the device's software. Additionally, as an example, the probe may be applied after the fingerprint sensor system is fully installed in a finished electronic device. In this way signals and images may be obtained from the probe by the device's software.

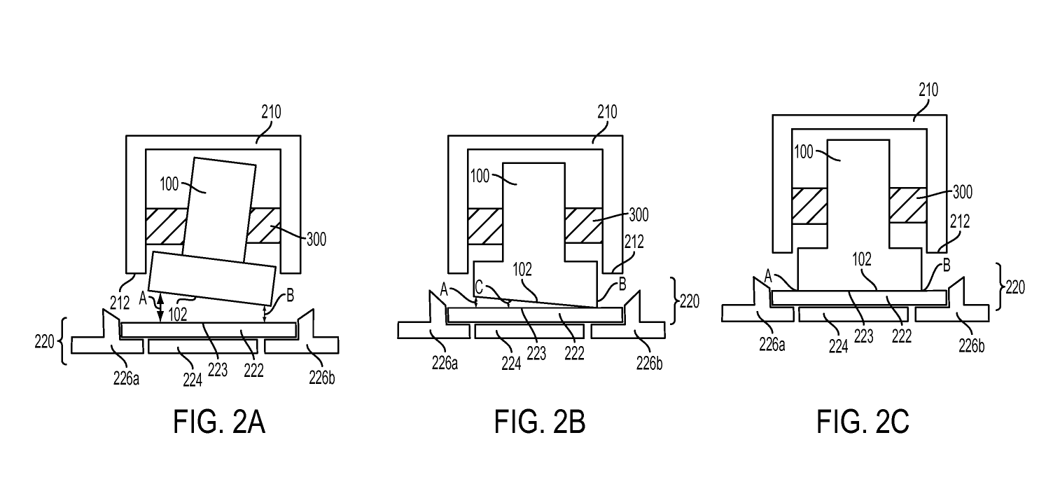

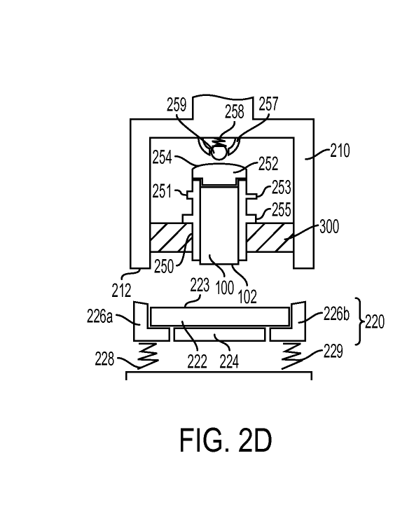

FIGS. 2A-C show conceptual drawings of the probe coming into contact with a fingerprint module test platform.

As discussed above, consistency between probes may affect the testing or calibration of fingerprint sensors, as may consistency in the way the probe contacts the sensor module. Various controls and devices may be used to improve consistency of the application of probe 100 to a fingerprint module test platform 220, as will be discussed with respect to FIGS. 2A-2C.

In accordance with certain embodiments, the fingerprint sensor test and calibration system may include a probe 100 located at least partially inside of a housing 210. The probe may include a contact surface 102 that may extend below the bottom surface 212 of housing 210. The probe 100 and the housing 210 may be connected by a support bracket 300. The fingerprint test system may be operable to contact the probe 100, and specifically the contact surface 102 of the probe 100, against the fingerprint module test platform 220.

The fingerprint module test platform 220 may include a cover glass 222. The dielectric 112 discussed above may form a part of the cover glass, may be adhered to the cover glass or may be a separate layer than the cover glass. As shown here, the dielectric is a part of the cover glass layer 222. Below the cover glass layer 222 is the sensor 224 which corresponds with (sensor 122 above and the array of sensor elements 124 discussed above). Additionally, each of these various layers or components may be separated and held together by an adhesive. The cover glass layer 222 and the sensor 224 may be constrained on either end, for example by bracket 226A and bracket 226B. As discussed in more detail below, the bracket 226A and/or the bracket 226 may also be operable as a target or sighting system utilized by the test system (likewise, some other portion of the fingerprint module test platform 220 may be utilized as the target or sighting system).

The cover glass layer 222 may have an upper surface 223. During testing or calibration the probe contact surface 102 may contact the cover glass upper surface 223. Due to the tolerance stack-up in the construction of the fingerprint sensor test and calibration system which includes the fingerprint module test platform 220 or the probe and its associated components, the probe may not contact the upper surface 223 consistently. This inconsistency may occur between successive fingerprint module test platforms 220. This inconsistency may also occur between difference test or calibration systems. As shown in FIG. 2A, the probe 100 may approach the cover glass 222 with a difference in distance shown by arrow A versus a distance shown by arrow B. On contact as shown in FIG. 2B, distance B may be zero with a positive distance A. In an example, an difference between B and A of 10 microns, with A off the surface on one corner and B in contact, the whole image of the probe 100 may be slanted, giving a poor comparison with the known image of the probe 100.

In accordance with various embodiments, the fingerprint module test platforms 220 may be operable to adjust the probe 100 to facilitate a flat contact between the probe contact surface 102 and the contact surface 223, which may be a surface of a cover glass, input element, and the like (collectively referred to as a “cover glass contact surface”). In this embodiment, the bracket 226A/226B may be spring-loaded so that, as the probe 100 contacts the cover glass 222, the test platform 220 may adjust positions to accommodate for any misalignment between the probe and glass 222. For example, the test platform 220 may include separate springs 228/229 (see FIG. 2D) which support the brackets 226a/226b or the springs may be an integral part of brackets 226a/226b. The cover glass 222 may then adapt to the angle and/or position of the probe 100, utilizing the force provided by the spring-loaded brackets 226A/226B.

In accordance with various embodiments, the difference between the probe contact surface 102 and the cover glass contact surface 223 may be compensated for by the support bracket 300. The support bracket 300 may be operable to adjust the angle of the probe 100 around a plurality of axes. This flexibility around a plurality of axes may allow the probe 100 to adapt to the angle of the cover glass 222. In various examples, the support bracket 300 may be operable to adjust the angle of the probe 100 to lay flat against the cover glass 222, lay substantially flat against the cover glass 222, have less than a 10 micron gap at one edge of the probe 100 (represented by arrow A in FIG. 2B) or have an angle of less than 1.3 degrees relative to the cover glass 222 (represented by angle C).

Abutting the probe 100 against the cover glass 222 may result in the upward force from the cover glass 222. While this upward force may be controlled, the system may absorb this force. In various embodiments, the support bracket 300 may be ridged or inflexible in a direction parallel to the vector of the exerted force, allowing the force to travel through the probe 100 into bracket 300 into the housing and out to the rest of the system, as discussed in more detail below, causing the rest of the system to absorb the force. However, in other embodiments, the support bracket 300 may not be rigid or inflexible in the direction of the force. As such, in many embodiments either the support bracket 300 absorbs and deflects under the force or the force is translated out of the probe through an alternative device.

As shown in FIG. 2D, a device may be utilized to limit or prevent support bracket 300 from absorbing excessive force. In accordance with one embodiment, the support bracket 300 may include a probe collar 250. The probe 100 may slide into and out of probe collar 250 allowing the probe 100 to be easily removable from the system. The probe collar may include a rim 255 that extends around the circumference of the probe collar 255. This rim may be attachable to the support brackets discussed herein. The probe collar 255 may have a set screw 251 that secures the probe 100 inside of the collar. The probe collar 255 may also have a pin 253 which engages probe 100. This pin may allow different-sized or -shaped probes inserted into the probe collar 255 to all be clocked to the same angle. The probe collar may include or connect with a cap 252. The cap may be located on the end of the probe collar which is opposite the contact surface 102 of probe 100. Attached on the inside of the housing 210 there may a spring 258 and a ball bearing 259. The spring 258 and ball bearing 259 may be retained within a bracket 257 such that a portion of one side of the ball bearing is exposed to contact with the cap 252. The entire bracket may be a part of a screw that is adjustable in height allowing adjustment to contact the cap 252. The ball bearing may ride on a curved surface 254 on the outside of the cap 252. The curved surface may extend in all directions within housing 210 such that, regardless of the direction that probe 100 rotates through the freedom provided by support bracket 300, the ball bearing 259 stays in contact with the curved surface 254. In a sense, this embodiment works similarly to the concept of how a ballpoint pen works. The result is that probe 100 may still pivot to match the alignment of cover glass 222, but then upward force is translated up through the ball bearing 259 and spring 258 and into housing 210 and out to the rest of the system, rather than across the portion of support bracket 300 that enables the freedom about the plurality of axes. In another embodiment, the ball bearing 259, spring 258, and bracket 257 may form an end of the probe 100 or probe collar 250. In this embodiment, the cap 252 and surface 254 would form an inside of the housing 210. However, in this embodiment, the profile of surface 254 would be inverted from the previous embodiment to be concave and not convex. This may allow the ball bearing to stay in contact with the surface 254 through the range of travel of the probe 100.

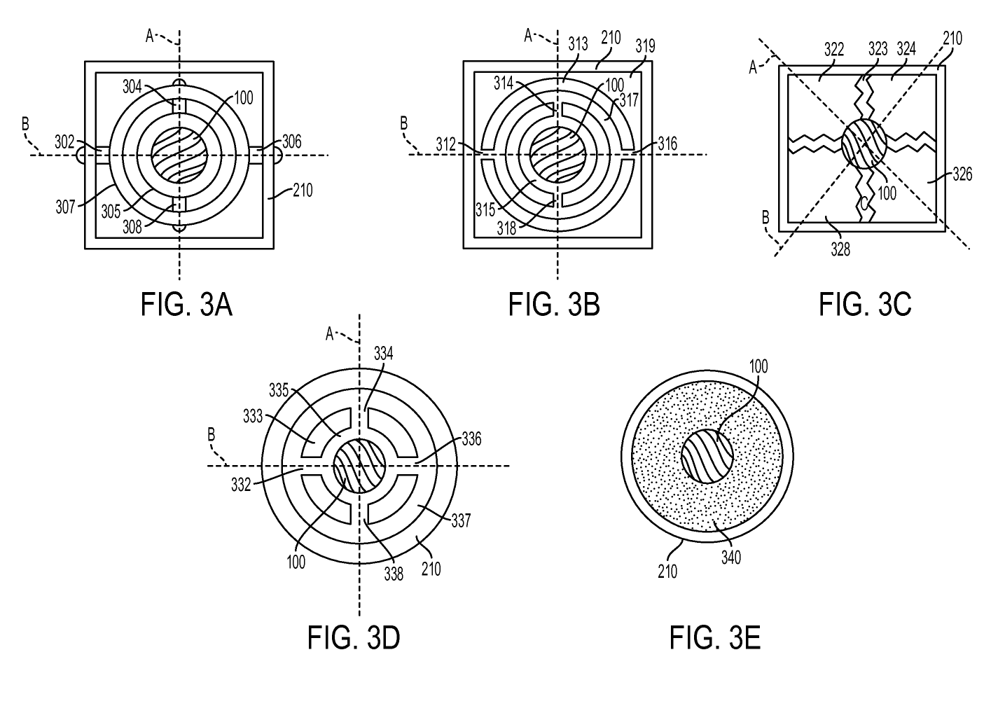

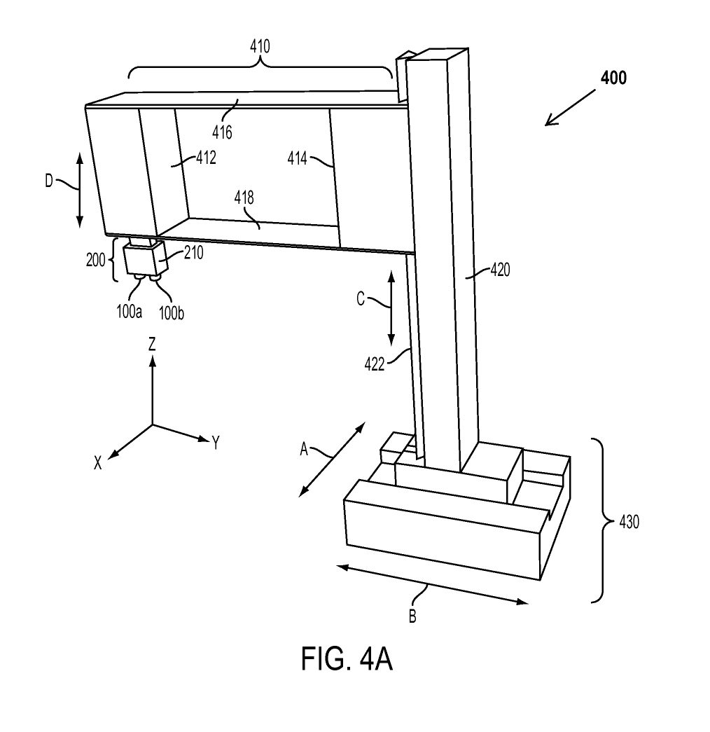

The support bracket 300 may include a variety of different configurations to allow the support bracket 300 to be operable about a plurality of axes. FIGS. 3A-E show example devices that support the probe and allow it to be free about at least two axes.

In accordance with various embodiments, the support bracket 300 may be a gimbal style device. FIG. 3A shows a probe supported by a gimbal style device. Probe 100 may be attached to an inner support structure 305. The inner support structure 305 could be any support structure attached to the probe 100 such as a collar, a bracket, a clamp or the like. The support structure 305 may also be integral to the probe 395. The inner support structure 305 may be connected to an outer support structure 307 by connection 304/308. Connection 304/308 may be pivot points or hinges that allow the probe 100 and the inner support structure 305 to rotate about axis A. The outer support structure 307 may be connected to the housing 210 by connections 302/306. Connections 302/306 may be pivot points or hinges that allow the probe 100, the inner support structure 305, and the outer support structure 307 to rotate about axis B. It should be appreciated that the connections permit motion of the inner and outer support structures relative to one another. As such, this system provides the probe 100 freedom to rotate about two axes, which in turn may allow probe 100 to adapt to any misalignment of a contact surface.

In accordance with various embodiments, the support bracket 300 may mimic a gimbal-style device. FIG. 3B shows a probe supported by a device that allows freedom about two axes. Specifically, the device as shown in FIG. 3B is made from a sheet of material. This sheet of material connects the probe 100 to the housing 210. Probe 100 may be attached to an inner support structure 315. The inner support structure 315 could be any support structure attached to the probe 100 such as a sheet collar.

The inner support structure 315 may be connected to an outer support structure 317 by connection 314/318. The outer support structure 317 may be formed from a unitary sheet of material. Connection 314/318 may be a small bridge made up of the same sheet of material. A bridge may extend between the inner support structure 315 and an outer support structure 317.

The connection 314/318 may allow probe 100 and the inner support structure 305 to deflect or rotate about an axis A. The outer support structure 317 may be connected to the housing 210 by connections 312/316. Connections 312/316 may be a small bridge made up of the same sheet of material. The bridge may extend between the inner support structure 315 and an outer support structure 317 and allow the probe 100, the inner support structure 315, and the outer support structure 317 to deflect or rotate about an axis B. The shaded portions shown in FIG. 3B represent slots 313 cut from a single sheet of material to form the various elements of the device. The sheet of material may be any material suitably strong to support the probe 100 and sustain the force of the probe against the cover glass. In various examples, the sheet of material may be spring steel. As such, this system provides the probe 100 freedom to rotate about two axes, which in turn may allow probe 100 to adapt to any misalignment of a contact surface.

In certain embodiments, the support bracket 300 may be a device that utilizes the flexibility of a sheet of material similar to the device shown in FIG. 3B. As one example, FIG. 3C shows a probe supported by a plurality of sheets of material that allows freedom about two axes. Specifically the device as shown in FIG. 3C includes first sheet 322, second sheet 324, third sheet 326, or fourth sheet 328. Sheets 322, 324, 326, or 328 may connect the probe 100 to the housing 210. Slots 323 are cut between the various sheets 322, 324, 326, or 328 to form the various elements of the device. The slots 323 allow the various elements to deflect or otherwise move independently of each other. The flexibility inherent in sheets 322 and 326 may allow the probe 100 to rotate about axis A. The flexibility inherent in sheets 324 and 328 may allow the probe 100 to rotate about axis B. As such, this system provides the probe 100 freedom to rotate about two axes, which in turn may allow probe 100 to adapt to any misalignment of a contact surface.

In other embodiments, the support bracket 300 may be a device that utilizes the flexibility of a sheet of material similar to the device shown in FIGS. 3B and 3C. As another example, FIG. 3D shows a probe supported by a device that allows freedom about two axes. Specifically, the device as shown in FIG. 3D is made from a sheet of material. This sheet of material connects the probe 100 to the housing 210. Probe 100 may be attached to an inner support structure 335. The inner support structure 335 could be any support structure attached to the probe 100 such as a sheet collar. The inner support structure 335 may be connected to an outer support structure 337 by connection 334/338. The outer support structure 337 may be a sheet of material. Connection 334/338 may be a small bridge made up of the same sheet of material. The bridge may extend between the inner support structure 335 and an outer support structure 337. The connection 334/338 and the natural flexibility of the sheet of material may allow probe 100 and the inner support structure 305 to deflect or rotate about axis A. The outer support structure 337 may be connected to the housing 210 by connections 332/336. Connections 332/336 may be a small bridge made up of the same sheet of material. The bridge may extend between the inner support structure 335 and an outer support structure 337. The natural flexibility of the sheet of material and the connections 332/336 may allow the probe 100 and the inner support structure 335 to deflect or rotate about axis B. Slots 333 are cut from a single sheet of material to form the various elements of the device. The sheet of material may be any material suitably strong to support the probe 100 and sustain the force of the probe against the cover glass. In various examples, the sheet of material may be spring steel. While the device shown in FIG. 3D may have less flexibility due to its geometric design than the device shown in FIG. 3B, this device may none-the-less provide the probe 100 freedom to rotate about two axes, which in turn may allow probe 100 to adapt to any misalignment of a contact surface.

In accordance with various embodiments, the support bracket 300 may be a device that utilizes the flexibility of a flexible material. For example, FIG. 3E shows a probe supported by a large flexible material which allows freedom about two axes. Specifically, the device as shown in FIG. 3E may include, for example, a gel, a rubber, a silicone or any suitably flexible material. The flexible material 340 may surround and connect the probe 100 to the housing 210. For example, a large rubber compression pad may connect probe 100 to housing 210. The flexibility inherent in a flexible material 340 may allow the probe 100 to rotate or deflect about any axis. As such, this system provides the probe 100 freedom to rotate about a plurality of axes, which in turn may allow probe 100 to adapt to any misalignment of a contact surface.

Generally, the support bracket 300 may be moved down the probe as close to the contact surface 102 as possible without interfering with the contact of the contact surface 102 with the upper surface 223 on the cover glass 222. If a support bracket 300 is used with a flexible material or a flexible design, a device, such as one discussed above with reference to FIG. 3D, may be utilized to prevent the flexible material or flexible design from absorbing the force applied against the probe 100.

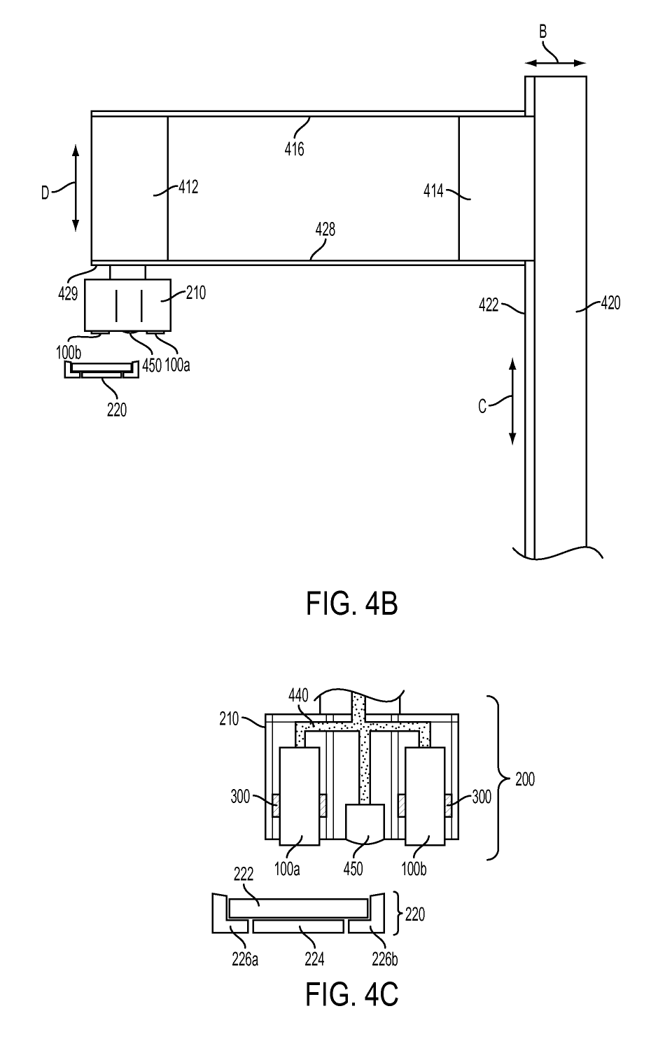

In accordance with various embodiments, a testing apparatus 400 may be utilized to locate and otherwise drive the probe 100 to the fingerprint sensor test platforms 220. FIGS. 4A-C show an example apparatus for applying a probe to a fingerprint sensor.

FIG. 4A illustrates an isometric example of a testing apparatus 400 that may include a base 430, an intermediate base 420, an arm 410, and a probe housing assembly 200. The base 430 may be movable in the x and y axis also shown in FIG. 4A in according to arrows A and B. This movement allows the base 430 to place the entire testing apparatus 400 in any location in the x-y plane. This freedom allows the testing apparatus 400 to locate the probe housing assembly 200 and move between separate fingerprint sensor test platforms 220 in order to test an assembly line. This freedom allows the testing apparatus 400 to locate the probe 100 above a single test platform 220 for testing. The intermediate base 420 may be attached to base 430. The connection between base 430 and intermediate base 420 may be a movable connection, allowing intermediate base 420 to move according to arrow B relative to base 430. The arm 410 may be movably attached to intermediate base 420. The arm 410 may move relative to base 420 according to arrow C. This movement allows the arm 410 to place the probe housing assembly 200, which may be attached to the bottom of arm 410, in any location in the on the z axis. This movement may drive the probe housing assembly 200 toward a targeted fingerprint sensor test platform 220. The arm may be attached to base 420 along track 422.

In accordance with one embodiment, the arm 410 may be a device which is operable to move according to arrow C in FIGS. 4A and 4B. The arm 410 may also be operable to flex (such as according to arrow D in FIGS. 4A and 4B) in order to absorb the force input into probe 100 on contact with the cover glass 222. The arm 410 may also be operable to keep the probe housing assembly 200 substantially rigid in the vertical z axis despite flexing under force. Keeping the probe housing assembly 200 steady in the vertical z axis aids in limiting the angular difference between the contact surface 102 of probe 100 and the upper surface 223 of cover glass 222. To attain this operability, the arm 410 may comprise an upper plate 416 and a lower plate 418. The upper and lower plates 416/418 may sandwich a first block 412 and a second block 414 between the two plates. The blocks, which may be spaced apart from one another, may be located at each end of the upper and lower plates 416/418. Generally, the blocks may provide structural support to the upper and lower plates 416/418 and so to the overall arm 410.

In this structure, arm 410 is generally rectangular as shown in FIGS. 4A and 4B. The connection between the plates 416/418 and the blocks 412/414 may be sufficiently rigid that the plates and the blocks do not move relative to one another. In accordance with various embodiments, the blocks may be manufactured out of a variety of different materials. For example, blocks may be formed from aluminum, titanium, steel, various polymers (e.g. acetal, nylon, etc.). The blocks may each be made out of a different material or they may be made out of the same material. In one example, the first block 412 may be a conductive material such as aluminum and the second block 414 may be a low friction material such as an acetal resin (e.g., delrin). In another example, the second block 414 may be a strong, light material such as aluminum while the first block 412 may be a machine-able, lightweight, non-conductive material such as an acetal resin (e.g. delrin). The plates 416/418 may be made out of any thin, strong material. In one example, the plates may be spring steel.

The second block 414 or some attachment thereto may engage track 422. This end of arm 410 may be driven by the testing apparatus 400. As such, while it may be movable generally, it does not necessarily move in response to a force applied on the opposite end of the arm proximal to first block 412. Instead, in response to a force applied to the arm proximal to first block 412, the entire arm may flex or deflect, causing the rectangle of the arm to deform into a non-rectangular shape that approximates a parallelogram. The actual shape may depend, in part, on the stiffness of the plates 416/418 and the geometry of the arm. This configuration is particularly useful, as it may maintain the blocks 412/414 in a substantially vertical configuration even when flexed. As the probe housing assembly 200 is attached to the end 429 of the arm 410 proximal or under block 412, the probe housing assembly 200 may also maintain its vertical alignment in the z axis. The structure of the arm 410 may also be controlled such that the arm imparts the desired reactive force back into the probe in response to the probe contacting the cover glass and deflecting the arm. As discussed above, the force of the probe against the cover glass is a characteristic that may be controlled for consistent measurement of the probe by the fingerprint sensor. In one embodiment, the testing apparatus 400 may overdrive the probe 100 into the cover glass by a millimeter. The thickness and length of the plates 416/418, may be selected in order to apply the desired force at one millimeter, for example. Apparatus 400 may overdrive the probe 100 into the cover glass any distance, such as greater or less than a millimeter.

In accordance with various embodiments, the testing apparatus 400 may include a probe housing assembly 200 that has a plurality of probes, such as probe 100b and 100a as shown in FIGS. 4A-4C. As indicated previously, more than one probe may be utilized, for example, to represent multiple classes of fingers. Additionally or alternatively, more than one type of probe may be utilized in the system.

As such, and as shown in FIG. 4C, the probe housing assembly 200 may include housing 210 which houses probe 100a and probe 100b. Depending on the requirements of the system, the probe may be grounded via wiring 440 or the probes may receive various signals via wiring 440. The probes 100a/100b may each have a separate support bracket 300 operable as discussed herein. In an alternative embodiment, the probes may be grounded through the support bracket 300.

The probe housing assembly 200 may also include a camera 450. The camera may be positioned anywhere on the housing assembly 200. In one example, the camera faces down, allowing it to see a target and provide feedback to the testing apparatus 400. The feedback enables testing apparatus 400 to position probes 100a/100b based on the images provided from the camera. Accordingly, the testing apparatus 400 may be operable to utilize feedback from the camera and place a probe on the fingerprint module test platform 220. As shown in FIGS. 4A-C the camera may be located between the two probes within the housing. The camera may alternatively be placed outside of the housing or on either side of the two probes, thereby allowing the camera and probes to move together.

In accordance with various embodiments, the fingerprint module test platform 220 may have visual indicators for the camera 450 to cue off of. For example, the fingerprint module test platform 220 may include a target. The target may be a mark located on the cover glass 222, on the fingerprint sensor 224, under the cover glass 222/fingerprint sensor 224, or as part of some other feature. In one example, the target may be brackets 226a or 226b. The brackets 226a or 226b may form a boundary around the entire test platform 220. The camera may visualize this entire boundary and interpolate the center of the fingerprint sensor as the location to which to lower the probe.

Brackets 226a/226b may be formed as a single ring (which may be circular, rectangular, or another shape) around the test platform 220. Understanding the structure of the test platform and the location of the ring formed by brackets 226a/226b, the camera can calculate and locate the fingerprint sensor. In another embodiment, the brackets 226a/226b do not form a ring but are merely separate elements on either side of the test platform. None-the-less, the camera may utilize their visual image and location relative to the fingerprint sensor to locate the probe. The brackets 226a/226b may be made from a conductive material such as aluminum or stainless steel.

As the entire assembly may be movable in three degrees (e.g. along the x, y, and z axes), when a test platform 220 is first loaded for testing or calibration the camera may be sitting above the test platform looking down. The camera may look down at the test platform and use the target as its reference.

As an example, the area of the fingerprint sensor to be tested or calibrated may be approximately 4.4 millimeters across. The bracket 226a/226b is located outside of this area. The probe may be, for example, 8 millimeters in diameter. As such, the probe may be larger than the sensor area to be tested. The design of test platform 220 may maintain the sensor area to be tested or calibrated at an equidistant from the bracket 226a/226b. To improve the repeatability of the testing and calibration the probe may also be equidistant from bracket 226a/226b so there is limited interaction between the probe and the bracket 226a/226b from one tester to another. The interaction between the probe 100 and the bracket 226a/226b may result in some coupling, which may affect the image if not centered.

As such, the location of the probe in the x and y direction may improve overall test and calibration results by centering in the bracket 226a/226b and the probe 100 relative to one another. The camera may use the bracket 226a/226b in its pattern recognition software as its reference for providing positioning feedback to the testing apparatus. Each testing apparatus 400 may be trained to know exactly how far it is from the bracket 226a/226b to the center of the sensor to be tested or calibrated. By initiating a one-time calibration may set up a permanent reference that from then on the camera may utilize when it looks at the ring. Thereafter the software may know the distance and position from the target to locate the probe 100 and move the probe 100 down to the test platform 220.

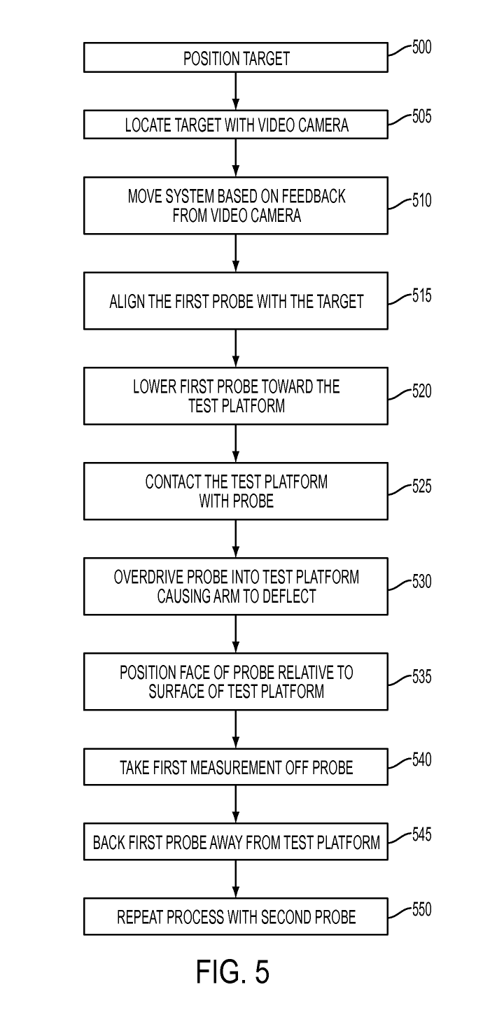

FIG. 5 shows an example flow chart depicting the method of using a fingerprint sensor probe.

As shown in operation 500, a target may be positioned under a fingerprint reader testing or calibration apparatus. More particularly, the target may include the full test platform as discussed above including the fingerprint sensor that is the focus of the operation. As the testing or calibration apparatus primarily functions on feedback provided by the camera viewing the target, the presence of the target may allow the system to accurately locate the position of the fingerprint sensor.

Once the target is located under the fingerprint reader testing or calibration apparatus, the camera may locate the target as shown in operation 505. As indicated above, the bracket 226A or the bracket 226 may be operable as a target utilized by the test system. The camera may then record an image of the target. Each testing apparatus may be trained to know exactly how far it is from the target (e.g. bracket 226a/226b) to the center of the sensor. This one-time calibration may be accomplished prior to the first test or calibration by the testing apparatus. The initial calibration sets that up so that from then on when the camera looks at the target, the camera knows how far to move the system to put the first probe down and how far to move the system to put the second probe down.

Based on the recognition of the target provided in operation 505, the fingerprint reader testing or calibration apparatus may analyze the feedback from the camera image and utilize the calibration information obtained from the one-time calibration. The testing apparatus may then move the probe toward the fingerprint sensor according to operation 510. Then according to operation 515, the first probe may be aligned with the center of the fingerprint reader. This movement and alignment may be accomplished by the freedom of the testing or calibration apparatus to move in the x and y axis.

Once the probe is aligned with the fingerprint sensor in the test platform, the probe may be lowered onto the test platform according to operation 520. This lowering may be accomplished by the freedom of the testing or calibration apparatus, specifically the arm relative to the intermediate base to move in the z axis. As shown in operation 525, the probe may then contact the test platform. Specifically, the contact surface of the probe may contact the upper surface of the cover glass as already discussed herein.

Once contact occurs, the probe may be overdriven into the test platform as shown in operation 530. In one embodiment, the testing apparatus may overdrive the probe into the cover glass by a millimeter. The desired force between the probe and the cover glass may be obtained by this overdrive. In various embodiments, the testing apparatus may overdrive the probe into the cover glass any distance, such as greater or less than a millimeter. The overdrive force may cause the arm of the testing apparatus to deflect. Despite the deflection, the arm may maintain the probe in a substantially vertical orientation.

In accordance with operation 535, the probe may re-position its contact surface relative to the surface of the cover glass on top of the test platform. As discussed herein, this repositioning may be accomplished by the freedom the probe enjoys about at least two axes due to the specific support bracket employed by the probe in its connection with the probe housing. In response to the force against the cover glass, the probe may utilize the axial freedom to match the slope and surface of the cover glass.

Once in full contact, as shown in operation 540, the first signal measurement may be taken off the probe. In the probe position, the probe may be in contact with the test platform in the same manner as a real finger could be. However, because the probe is specifically designed to have a known signal, the measured signal may be extracted and compared to the known signal. Once the probe signal is measured, the fingerprint system can verify its accuracy and make any necessary calibrations to improve that accuracy.

After successful measurement of the first probe, the first probe may be backed away from the test platform as shown in operation 545. The entire process may be repeated on the same test platform with a second probe as shown in operation 550 or the entire process may be repeated on a new test platform with a new sensor.

As used throughout this document in each of the embodiments, aspects, examples, lists and various descriptions of the subject matter contained herein, the word “or” is intended to be interpreted in its inclusive form (e.g. and/or) not in its exclusive form (e.g. only one of) unless explicitly modified to indicate only one item in a list is intended (e.g. only one of A, B, or C). For example, the phrase A, B, or C is intended to include any combination of the elements. The phrase can mean only A. The phrase can mean only B. The phrase can mean only C. The phrase can mean A and B. The phrase can mean A and C. The phrase can mean B and C. The phrase can mean A and B and C. This concept extends to any length of list (e.g., 1, 2, 3 . . . n) used herein.

Although the foregoing discussion has presented specific embodiments, the foregoing merely illustrates the principles of the invention. Persons skilled in the art will recognize that changes may be made in form and detail without departing from the spirit and scope of the disclosure as various modifications and alterations to the described embodiments will be apparent to those skilled in the art, in view of the teachings herein. For example, the processing steps may be performed in another order, or in different combinations. It will thus be appreciated that those having skill in the art will be able to devise numerous systems, arrangements and methods which, although not explicitly shown or described herein, embody the principles of the disclosure and are thus within the spirit and scope of the present invention. From the above description and drawings, it will be understood by those of ordinary skill in the art that the particular embodiments shown and described are for purposes of illustration only, and references to details of particular embodiments are not intended to limit the scope of the present invention, as defined by the appended claims.

We claim:

1. A probe apparatus comprising:
a housing;
a probe having a contact surface that extends below the bottom surface of the housing and operably attached to the housing;
a support bracket having freedom about at least two axes and connected to the probe; wherein
the probe is operable to move freely about at the least two axes to adapt to a misalignment of the contact surface with another surface.

2. The apparatus of claim 1, wherein the support bracket connects the probe to the housing.

3. The apparatus of claim 2, wherein the support bracket includes an inner structure that is attached to the probe.

4. The apparatus of claim 3, wherein the support bracket includes an outer structure connected to the inner structure by a first connection along a first axis.

5. The apparatus of claim 4, wherein the support bracket includes a second connection which connects the ouster structure to the housing along a second axis that is 90 degrees offset from the first connection.

6. The apparatus of claim 5, wherein the connection along the first axis and the second axis is a hinge.

7. The apparatus of claim 5, wherein the connection along the first axis and the second axis is a is a strip of sheet metal.

8. The apparatus of claim 2, wherein the support bracket includes four separate strips of sheet metal that are sufficiently flexible to allow the probe to separately flex each of the four separate strips of metal giving the probe freedom about at least 2 axes.

9. The apparatus of claim 2, wherein the support bracket is a gel which surrounds and supports the probe connecting the probe to the housing.

10. A test fixture comprising:
an arm having an upper spring plate and a lower spring plate operable to maintain an un-fixed end of the arm in a substantially vertical orientation;
a probe housing attached to the bottom surface of the arm;
a probe located within the probe housing, the probe having a contact surface that extends from the housing and is operable to contact a flat surface; and
a support bracket having freedom about at least two axes and connecting the probe to the housing; wherein
the probe is operable to move freely about the at least two axes.

11. The test fixture of claim 10, further comprising a camera located with the probe housing.

12. The test fixture of claim 10, further comprising a second probe located in the probe housing.

13. The test fixture of claim 10, wherein the support bracket comprises a gimbal structure comprising:
an inner support structure;
an outer support structure; and
a plurality of flexible connectors between the inner and outer support structures, the plurality of flexible connectors permitting motion of the inner support structure with respect to the outer support structure.

14. The test fixture of claim 10, wherein the arm comprises:
a first and a second non-conductive block sandwiched between the upper spring plate and the lower spring plate; wherein
the two non-conductive blocks are separated with each one located at the ends of the spring plate; and
the spring plate is operative to flex vertically while maintaining the blocks in a substantially vertical alignment.

15. The test fixture of claim 14, further comprising:
a base support connected to one of the two non-conductive blocks opposite the end of the arm connected to the probe housing; wherein
the base support is operable to move the arm along a z axis; and
the base support is operable to move the entire test fixture in the x and y directions.

16. A method for testing a capacitive array comprising:
lowering a first probe toward a test platform;
contacting the test platform with a contact surface of the first probe;
determining if the first probe is in angular alignment with the test platform;
if not, repositioning the contact surface of the first probe relative to a surface of test platform; and
taking a first measurement from the probe based on the first probe's capacitive profile.

17. The method of claim 16 further comprising:
positioning a target associated with the test platform;
locating the target with a video camera that is a apart of an apparatus holding the first probe;
moving the apparatus holding the first probe based on feedback from the video camera; and
aligning the first probe with the test platform based on position of the target.

18. The method of claim 16 further comprising:
overdriving the first probe into test platform causing an arm, that is a part of the apparatus holding the first probe, to deflect and forcing the first probe against the test platform based on the deflection caused by the arm.

19. The method of claim 16 further comprising:
hacking the first probe away from the test platform.

20. The method of claim 16 further comprising:
repeating the process with a second probe that is a part of the apparatus holding the first probe.
